(19) United States
(12) Patent Application Publication
(10) Pub. No.: US 2022/0083849 A1
(43) Pub. Date: Mar. 17, 2022

(54) SWITCHING CIRCUIT AND STORAGE DEVICE

(71) Applicant: Kioxia Corporation, Tokyo (JP)

(72) Inventors: Katsuyoshi KOMATSU, Yokkaichi Mie (JP); Kenichi MUROOKA, Yokkaichi Mie (JP); Tadaomi DAIBOU, Yokkaichi Mie (JP); Yuichi ITO, Yokkaichi Mie (JP)

(73) Assignee: Kioxia Corporation, Tokyo (JP)

(21) Appl. No.: 17/461,093

(22) Filed: Aug. 30, 2021

(30) Foreign Application Priority Data
Sep. 11, 2020 (JP) 2020-152882

(51) Int. Cl. G06N 3/063

(52) U.S. Cl. CPC G06N 3/0635

(57) ABSTRACT

A switching circuit includes: a first circuit including a first capacitor, a first resistor, and a first selector above the first capacitor and resistor; and a second circuit including a second capacitor, a second resistor, and a second selector above the second capacitor and resistor. The capacitors have: a first and a second lower electrode on a semiconductor substrate; a dielectric layer on the lower electrodes; a resistive layer on the dielectric layer to form the resistors with the dielectric layer; a first upper electrode on the resistive layer opposite to the first lower electrode to form the first capacitor with the first lower electrode; and a second upper electrode on the resistive layer opposite to the second lower electrode to form the second capacitor with the second lower electrode.

### CROSS-REFERENCE TO RELATED APPLICATION

This application is based upon and claims the benefit of priority from Japanese Patent Application No. 2020-152882, filed on Sep. 11, 2020; the entire contents of which are incorporated herein by reference.fig.

### FIELD

Embodiments described herein relate generally to a switching circuit and a storage device.

### BACKGROUND

In recent years, the development of neural network technology using a neuron circuit has been progressing.

### BRIEF DESCRIPTION OF THE DRAWINGS

FIG. 1 is an explanatory circuit diagram of a circuitry example of a switching circuit.

FIG. 2 is an explanatory upper view of a structure example of the switching circuit.

FIG. 3 is an explanatory sectional view of the structure example of the switching circuit.

FIG. 4 is an explanatory sectional view of the structure example of the switching circuit.

FIG. 5 is an explanatory schematic view of a structure example of a storage device using a neuron circuit.

### DETAILED DESCRIPTION

A switching circuit of an embodiment includes: a first circuit including a first capacitor, a first resistor and a first selector, the first resistor being serially connected to the first capacitor, and the first selector being provided above the first capacitor and the first resistor and being parallelly connected to the first capacitor; and a second circuit including a second capacitor, a second resistor and a second selector, the second resistor being serially connected to the second capacitor, the second selector being provided above the second capacitor and the second resistor, the second selector being parallelly connected to the second capacitor, and the second circuit being connected to the first circuit through the second resistor. The first and second capacitors have: a first and a second lower electrode provided on a semiconductor substrate; a dielectric layer provided on the first and second lower electrodes; a resistive layer provided on the dielectric layer to form the first and second resistors with the dielectric layer; a first upper electrode provided on the resistive layer opposite to the first lower electrode to form the first capacitor with the first lower electrode; and a second upper electrode provided on the resistive layer opposite to the second lower electrode to form the second capacitor with the second lower electrode.

Embodiments will be hereinafter described with reference to the drawings. A relation of the thickness and planar dimension of each constituent element illustrated in the drawings, a thickness ratio among the constituent elements, and so on may be different from actual ones. Further, in the embodiment, substantially the same constituent elements are denoted by the same reference signs, and a description thereof will be omitted when appropriate.

In this specification, “connection” includes not only physical connection but also electrical connection.

### First Embodiment

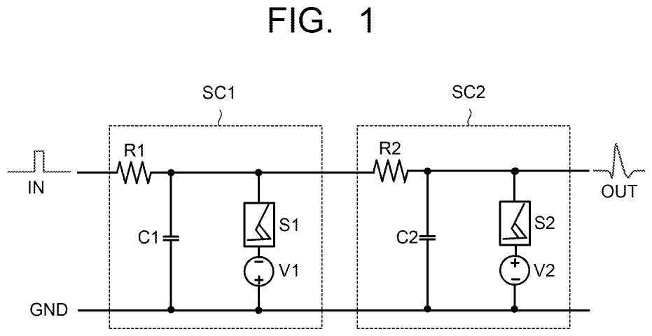

A circuitry example of a switching circuit will be hereinafter described. FIG. 1 is an explanatory circuit diagram of the circuitry example of the switching circuit. The switching circuit includes: a first circuit SC1 including a first capacitor C1, a first resistor R1, and a first selector S1; and a second circuit SC2 including a second capacitor C2, a second resistor R2, and a second selector S2.

One terminal of the first resistor R1 is connected to a signal line for receiving, for example, an input signal IN.

The first capacitor C1 is serially connected to the first resistor R1. An upper electrode of the first capacitor C1 is connected to the other terminal of the first resistor R1. A lower electrode of the first capacitor C1 is connected to a wiring line for supplying, for example, a ground potential GND.

The first selector S1 is connected parallelly to the first capacitor C1. A first electrode of the first selector S1 is connected to the other terminal of the first resistor R1. A second electrode of the first selector S1 is connected to a power source for supplying a first voltage V1. The first voltage V1 is, for example, a positive voltage.

One terminal of the second resistor R2 is connected to the other terminal of the first resistor R1 and the first electrode of the first selector S1. Accordingly, the second circuit SC2 is connected to the first circuit SC1 through the second resistor R2.

The second capacitor C2 is serially connected to the second resistor R2. An upper electrode of the second capacitor C2 is connected to the other terminal of the second resistor R2. A lower electrode of the second capacitor C2 is connected to the wiring line for supplying, for example, the ground potential GND. The capacitance of the second capacitor C2 is larger than the capacitance of the first capacitor C1.

The second selector S2 is connected parallelly to the second capacitor C2. A first electrode of the second selector S2 is connected to the other terminal of the second resistor R2. A second electrode of the second selector S2 is connected to a power source for supplying a second voltage V2. The second voltage V2 is, for example, a negative voltage.

The first selector S1 and the second selector S2 are nonlinear resistance switching elements. The first selector S1 and the second selector S2 turn on when a voltage exceeding a threshold voltage is applied.

The switching circuit illustrated in FIG. 1 is applicable to, for example, a neuron circuit. The neuron circuit is a circuit unit configuring a neural network.

A neuron is a cell forming a nerve of a living organism. A living organism contains a plurality of ions inside and outside a cell membrane of the neuron, and a membrane potential is formed according to a difference in the concentration of the ions between the inside and the outside of the cell membrane.

The cell membrane of the neuron has a potassium channel permeable to only potassium ions (K¹⁰) and a sodium channel permeable to only sodium ions (Na⁺).

When the aforesaid cell membrane is at rest, the potassium channel and the sodium channel are closed. A membrane potential at this time is called a resting membrane potential.

A signal of an electric stimulus received by the neuron causes a temporary change in the membrane potential. First, hyperpolarization occurs, and therefore, the sodium channel opens, so that the sodium ions move from the outside to the inside of the cell membrane. This makes the membrane potential lower than the resting membrane potential. Next, depolarization occurs, and therefore, the potassium channel temporarily opens, so that the potassium ions flow from the inside to the outside of the cell membrane. This makes the membrane potential higher than the resting membrane potential. Thereafter, when the membrane potential exceeds a certain value, the potassium channel and the sodium channel close, but since the sodium ions and the potassium ions move through the cell membrane, the membrane potential becomes lower than the resting membrane potential and thereafter returns to the resting membrane potential. Through these operations, a spike signal having a spike according to the change in the membrane potential is formed. The operation of forming the aforesaid spike signal is also called firing behavior.

The switching circuit illustrated in FIG. 1 includes the first selector S1 corresponding to the sodium channel and the second selector S2 corresponding to the potassium channel and is capable of forming a spike signal by changing a voltage value of the output signal OUT by changing an on-state or an-off state of the first selector S1 and the second selector S2 according to a voltage value of the input signal IN. By doing so, the switching circuit is capable of imitating the neuron firing behavior of a living organism.

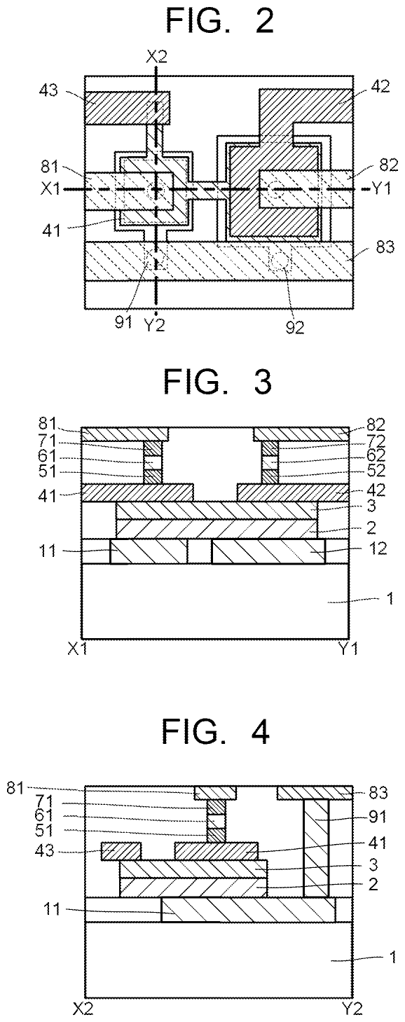

Next, a structure example of the switching circuit illustrated in FIG. 1 will be described below. FIG. 2 is an explanatory schematic upper view of the structure example of the switching circuit. FIG. 3 is an explanatory schematic sectional view of the structure example of the switching circuit, taken along the X1-Y1 line in FIG. 2. FIG. 4 is an explanatory schematic sectional view of the structure example of the switching circuit, taken along the X2-Y2 line in FIG. 1.

As illustrated in FIG. 2 to FIG. 4, the switching circuit illustrated in FIG. 1 includes an electrode 11, an electrode 12, a dielectric layer 2, a resistive layer 3, a conductive layer 41, a conductive layer 42, a conductive layer 43, an electrode 51, an electrode 52, a switching layer 61, a switching layer 62, an electrode 71, an electrode 72, a wiring line 81, a wiring line 82, a wiring line 83, a contact 91, and a contact 92. Between the constituent elements, an insulator such as silicon oxide (SiO₂) is provided as required. The constituent elements are formed using, for example, photolithography technology.

The electrode 11 and the electrode 12 are on a semiconductor substrate 1. The electrode 11 and the electrode 12 contain doped silicon that contains dopant such as phosphorus and boron, for instance. The electrode 11 and the electrode 12 are electrically insulated from each other by an insulator such as oxide silicon (SiO₂) provided on the semiconductor substrate 1, for instance. The electrode 11 forms the lower electrode of the first capacitor C1 illustrated in FIG. 1. The electrode 12 forms the lower electrode of the second capacitor C2 illustrated in FIG. 1.

The dielectric layer 2 is on the electrode 11. The dielectric layer 2 contains at least one material selected from the group consisting of hafnium oxide (HfO₃), hafnium silicate (HfSiO₄), zirconium silicate (ZrSiO₄), zirconium oxide (ZrO₂), strontium titanate (SrTiO₃), and barium strontium titanate (BaSrTiO₃), for instance. The use of these materials enables the dielectric layer 2 to have a higher dielectric constant.

The resistive layer 3 is on the dielectric layer 2. The resistive layer 3 contains, for example, polysilicon. The resistive layer 3 with the dielectric layer 2 forms the first resistor R1 illustrated in FIG. 1 in a region between the electrode 11 and the electrode 12, and forms with the dielectric layer 2 the second resistor R2 in a region between the electrode 11 and the conductive layer 43. The resistive layer 3 contains, for example, polysilicon. The use of the polysilicon enables the resistive layer 3 to stably have a high resistance.

The conductive layer 41 is on the resistive layer 3 opposite to the electrode 11. In other words, the conductive layer 41 is opposite the electrode 11 across the dielectric layer 2 and the resistive layer 3. The conductive layer 41 constitutes the upper electrode of the first capacitor C1 illustrated in FIG. 1.

The conductive layer 42 is on the resistive layer 3 opposite to the electrode 12. In other words, the conductive layer 42 is opposite the electrode 12 across the dielectric layer 2 and the resistive layer 3. The conductive layer 42 forms the upper electrode of the second capacitor C2 illustrated in FIG. 1. The switching circuit transmits the output signal OUT through the conductive layer 42.

The electrode 11 and the conductive layer 41 form the first capacitor C1 illustrated in FIG. 1. The electrode 12 and the conductive layer 42 form the capacitor C2 illustrated in FIG. 1. Note that making an overlapping area between the electrode 12 and the conductive layer 42 larger than an overlapping area between the electrode 11 and the conductive layer 41 enables the capacitance of the second capacitor C2 to be larger than the capacitance of the first capacitor C1.

The conductive layer 43 is on the resistive layer 3. The switching circuit receives the input signal IN through the conductive layer 43.

The conductive layer 41, the conductive layer 42, and the conductive layer 43 each contain at least one element selected from the group consisting of titanium, tungsten, copper, and aluminum, for instance.

The electrode 51 is on the conductive layer 41. The electrode 52 is on the conductive layer 42. The electrode 51 and the electrode 52 each contain at least one element selected from the group consisting of carbon, carbon nitride, titanium, titanium nitride, tungsten, tungsten nitride, copper, and aluminum, for instance. The electrode 51 forms the first electrode of the first selector S1 illustrated in FIG. 1. The electrode 52 forms the first electrode of the second selector S2 illustrated in FIG. 1.

The switching layer 61 is on the electrode 51. The switching layer 62 is on the electrode 52. The switching layer 61 and the switching layer 62 each contain at least one chalcogen element selected from the group consisting of sulfur, selenium, and tellurium.

The electrode 71 is on the switching layer 61. The electrode 72 is on the switching layer 62. The electrode 71 and the electrode 72 each contain at least one element selected from the group consisting of carbon, carbon nitride, titanium, titanium nitride, tungsten, tungsten nitride, copper, and aluminum, for instance. The electrode 71 forms the second electrode of the first selector S1 illustrated in FIG. 1. The electrode 72 forms the second electrode of the second selector S2 illustrated in FIG. 1.

The electrode 51, the switching layer 61, and the electrode 71 form the first selector S1 illustrated in FIG. 1. The electrode 52, the switching layer 62, and the electrode 72 form the second selector S2 illustrated in FIG. 1. When a voltage applied to the aforesaid switching layers is lower than the threshold voltage, the switching layers function as insulators, so that the first selector S1 and the second selector S2 turn off. When the voltage applied to the aforesaid switching layers exceeds the threshold voltage, the switching layers rapidly decrease in resistance value to function as conductive layers, so that the first selector S1 and the second selector S2 turn on.

The wiring line 81 is on the electrode 71. The wiring line 81 is connected to the power source for supplying the first voltage V1. The wiring line 82 is on the electrode 72. The wiring line 82 is connected to the power source for supplying the second voltage V2. The wiring line 83 is connected to the electrode 11 through the contact 91 and is connected to the electrode 12 through the contact 92. The wiring line 83 is connected to the wiring line for supplying the ground potential GND, for instance.

The wiring line 81, the wiring line 82, and the wiring line 83 each contain at least one element selected from the group consisting of titanium, tungsten, copper, and aluminum, for instance.

The contact 91 and the contact 92 each contain at least one element selected from the group consisting of titanium, tungsten, copper, and aluminum, for instance.

As described above, in the switching circuit of this embodiment, since the selectors are provided at a higher position from the semiconductor substrate than the capacitors and the resistors, a low-melting-point material, for example, polysilicon, is usable for the resistors even if high-temperature heat treatment is required when, for example, the capacitors and the resistors are formed.

It is difficult for a conventional CMOS-based neuron circuit to sufficiently imitate the neuron firing behavior. This may be a cause to prevent a processor such as GPU from having higher energy efficiency.

Know examples of a recent neuron circuit use a Mott insulator as a nonlinear resistance switching element. This neuron circuit more easily imitates a stochastic behavior as is done by a neuron. However, the neuron circuit using the Mott insulator is insufficient from a viewpoint of off-current and heat resistance.

On the other hand, the nonlinear resistance switching elements in the switching circuit of this embodiment are the chalcogenide-based selectors containing the chalcogen element. The chalcogenide-based selectors are advantageous for practical use because they have a higher heat resistance and a lower off-current than the Mott insulator. Further, the chalcogenide-based selectors can be formed by a process having a high affinity with a CMOS process, making it possible to make the manufacturing process less complicated.

### Second Embodiment

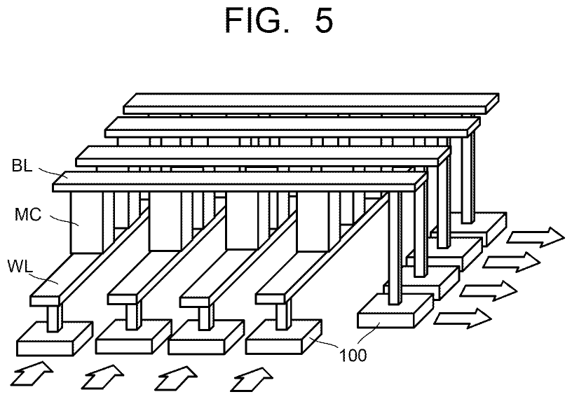

FIG. 5 is an explanatory schematic view of a structure example of a storage device using a neuron circuit. The storage device includes a plurality of neuron circuits 100 and a memory cell array (also called a cross-bar array) provided above the neuron circuits 100.

The neuron circuits 100 each correspond to the switching circuit of the first embodiment. The neuron circuits 100 are each connected to one of a plurality of word lines WL or one of a plurality of bit lines BL. The word lines WL and the bit lines BL extend in different directions. Note that the neuron circuit 100 connected to the word line WL or the neuron circuit 100 connected to the bit line BL does not necessarily have to be provided.

The memory cell array includes a plurality of memory cells MC. The memory cells MC are each connected to one of the word lines WL and one of the bit lines BL.

The memory cells MC each have a memory layer of, for example, a resistive random access memory (ReRAM), a phase-change memory (PCM), a magnetoresistive random access memory (MRAM), or a spin-transfer torque magnetic random access memory (STT-MRAM). These memory layers change in electrical resistance when a voltage exceeding a threshold voltage is applied thereto.

The storage device illustrated in FIG. 5 is capable of storing data when the voltage exceeding the threshold voltage is applied to the memory layer of the memory cell MC selected by the word line WL and the bit line BL to change the electrical resistance of the memory layer.

In the storage device illustrated in FIG. 5, by connecting the neuron circuit 100 to the word line WL, it is possible to input a spike signal to the word line WL from the input-side neuron circuit 100, for instance. Further, by connecting the neuron circuit 100 to the bit line BL, it is possible for the output-side neuron circuit 100 to generate the spike signal from an output signal from the bit line BL to output it, for instance.

As described above, the use of the neuron circuit 100 in the storage device enables to configure a neural network that imitates the behavior of a living organism. Since the neuron circuit 100 can be formed by a process having a high affinity with a CMOS process, the manufacturing process can be less complicated. Further, in the case where the above-described storage device is used as a processor such as GPU, its energy efficiency can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A switching circuit comprising:
a first circuit including a first capacitor, a first resistor and a first selector, the first resistor being serially connected to the first capacitor, and the first selector being provided above the first capacitor and the first resistor and being parallelly connected to the first capacitor; and
a second circuit including a second capacitor, a second resistor and a second selector, the second resistor being serially connected to the second capacitor, the second selector being provided above the second capacitor and the second resistor, the second selector being parallelly connected to the second capacitor, and the second circuit being connected to the first circuit through the second resistor,
wherein the first and second capacitors have:
a first and a second lower electrode provided on a semiconductor substrate;
a dielectric layer provided on the first and second lower electrodes;
a resistive layer provided on the dielectric layer to form the first and second resistors with the dielectric layer;
a first upper electrode provided on the resistive layer opposite to the first lower electrode to form the first capacitor with the first lower electrode; and
a second upper electrode provided on the resistive layer opposite to the second lower electrode to form the second capacitor with the second lower electrode.

2. The switching circuit according to claim 1,
wherein the first and second selectors each have:
a first electrode;
a second electrode; and
a switching layer provided between the first and second electrodes and containing at least one chalcogen element selected from the group consisting of sulfur, selenium, and tellurium.

3. The switching circuit according to claim 1, wherein the resistive layer contains polysilicon.

4. The switching circuit according to claim 1, wherein the dielectric layer contains at least one material selected from the group consisting of hafnium oxide, hafnium silicate, zirconium silicate, zirconium oxide, strontium titanate, and barium strontium titanate.

5. A storage device comprising:
a memory cell;
a word line connected to the memory cell;
a bit line connected to the memory cell; and
a neuron circuit connected to the word line or the bit line and including the switching circuit according to claim 1.

6. The storage device according to claim 5, wherein the memory cell has a memory layer of a resistive random access memory, a memory layer of a phase-change memory, a memory layer of a magnetoresistive random access memory, or a memory layer of a spin-transfer torque magnetic random access memory.
